(19) United States
(12) Patent Application Publication
(10) Pub. No.: US 2013/0229641 A1
(43) Pub. Date: Sep. 5, 2013

(54) DISTANCE METER

(71) Applicants: Oliver Wolst, Singapore (SG); Florian Giesen, Leinfelden (DE); Mike Uhlig, Stuttgart (DE); Heiko Fuellemann, Asperg (DE)

(72) Inventors: Oliver Wolst, Singapore (SG); Florian Giesen, Leinfelden (DE); Mike Uhlig, Stuttgart (DE); Heiko Fuellemann, Asperg (DE)

(73) Assignee: Robert Bosch GmbH, Stuttgart (DE)

(21) Appl. No.: 13/597,949

(22) Filed: Aug. 29, 2012

(30) Foreign Application Priority Data
Aug. 29, 2011 (DE) 20 2011 105 139.4

(51) Int. Cl. H05K 5/00

(52) U.S. Cl. CPC H05K 5/0086
USPC 356/4.01

(57) ABSTRACT

A distance meter includes a distance measuring mechanism, an evaluation unit configured to determine distance measured values, and an energy supply which is permanently installed in a housing of the distance meter. The energy supply is one or more rechargeable battery cells.

This application claims priority under 35 U.S.C. §119 to patent application no. DE 20 2011 105 139.4, filed on Aug. 29, 2011 in Germany, the disclosure of which is incorporated herein by reference in its entirety

### BACKGROUND

The disclosure is based on an electro-optical distance measuring apparatus.

Electro-optical distance measuring apparatuses, for example laser distance meters, have been commercially available for some time. These apparatuses make it possible, in a manner which is not tied to the power supply system and is relatively simple for the user, to contactlessly and very precisely measure distances in the range of a few centimeters to a few hundred meters.

DE-10213433 A1 discloses such a distance measuring apparatus of the generic type.

### SUMMARY

The disclosure is based on a distance meter, in particular a handheld electro-optical distance meter, having a transmitting and receiving device and an apparatus-internal evaluation unit for determining distance measurement data.

The measuring apparatus according to the disclosure has an apparatus-internal energy supply which is permanently installed inside the apparatus. According to the disclosure, this energy supply permanently integrated in the apparatus is one or more rechargeable battery cells or rechargeable batteries.

The terms “rechargeable battery cell” and “rechargeable battery” are intended to be used synonymously in the context of this application.

In the context of this application, the term “permanently installed” is intended to be understood as meaning that the energy supply is installed in the apparatus and cannot be readily changed by a user. Such a system differs from the conventional systems which are on the market and have batteries and a battery compartment which is accessible to the user in order to replace the batteries.

In principle, an energy supply permanently integrated in the housing of the apparatus can also naturally be removed from the apparatus, but this does not correspond to the apparatus-specific use and therefore is also not intended to argue against the term “permanently installed”.

In one advantageous embodiment, the one or more rechargeable battery cells installed in the apparatus are based on lithium chemistry.

These cells may be, for example, lithium ion cells or else lithium iron phosphate cells or else other lithium chemistries known to a person skilled in the art, for example lithium polymer structures.

The nominal or rated voltage of a rechargeable battery cell in the measuring apparatus according to the disclosure is typically in the range of 3 V to 5 V, in particular in the range of 3.5 V to 3.9 V and is particularly advantageously 3.7 V. However, it goes without saying that cells having other voltages are likewise possible.

In one advantageous embodiment of the measuring apparatus according to the disclosure, precisely one rechargeable battery cell, in particular a rechargeable battery cell in the voltage range of 3 V to 4 V, is provided.

The measuring apparatus according to the disclosure advantageously has a USB interface (USB: Universal Serial Bus) which is installed, in particular, in or on the apparatus.

It is particularly advantageous to design the interface as a micro USB interface.

The USB interface, in particular the micro USB interface, makes it possible to charge the energy supply installed in the measuring apparatus in the form of one or more rechargeable battery cells from the outside.

The USB interface, in particular the micro USB interface, advantageously has a cover which protects the interface from moisture and dust.

In one advantageous embodiment of the measuring apparatus according to the disclosure, a communication interface for data communication between the measuring apparatus, in particular the distance meter, and an external application is provided. This advantageously also makes it possible to transmit data and/or images from the measuring apparatus according to the disclosure which are stored, in particular, on PCs (computers), tablet PCs, PDAs (Personal Digital Assistants) or else so-called “smart phones” or other storage media.

This also simplifies the loading of measured values from the measuring apparatus directly into an application, for example into a drawing program for creating outlines or sketches.

On the other hand, it is possible to control the apparatus according to the disclosure from the outside via the communication interface and to operate said apparatus in the sense of a remote control, for example.

In one particularly advantageous embodiment of the measuring apparatus according to the disclosure, this communication interface is formed by the USB interface, in particular the micro USB interface.

Further advantageous refinements emerge from the following drawing and the associated description.

### BRIEF DESCRIPTION OF THE DRAWINGS

Further advantages emerge from the following description of the drawing. The drawing illustrates an exemplary embodiment of the disclosure. The drawing, the description and the claims contain numerous features in combination. A person skilled in the art will also expediently consider the features individually and will combine them to form expedient further combinations.

In the drawing:

FIG. 1 shows a measuring apparatus according to the disclosure in a view of the top side of the apparatus,

FIG. 2 shows the measuring apparatus according to the disclosure in a view of the underside of the apparatus.

### DETAILED DESCRIPTION

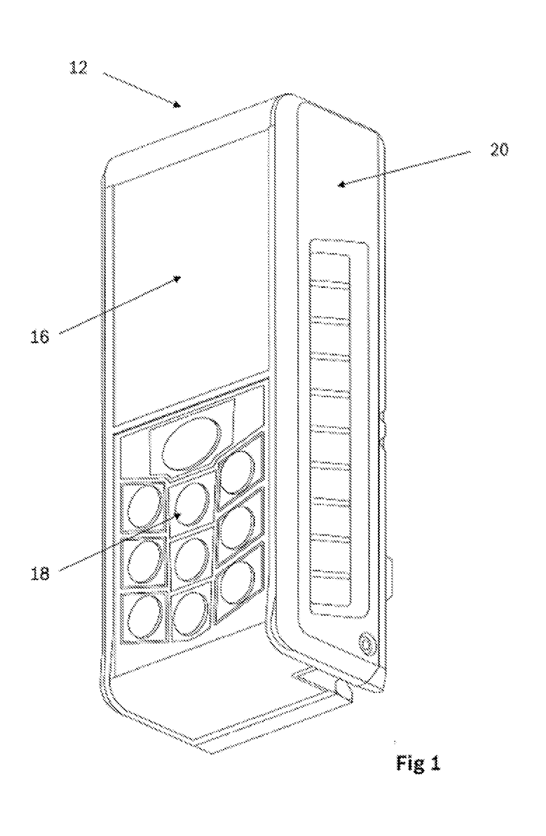

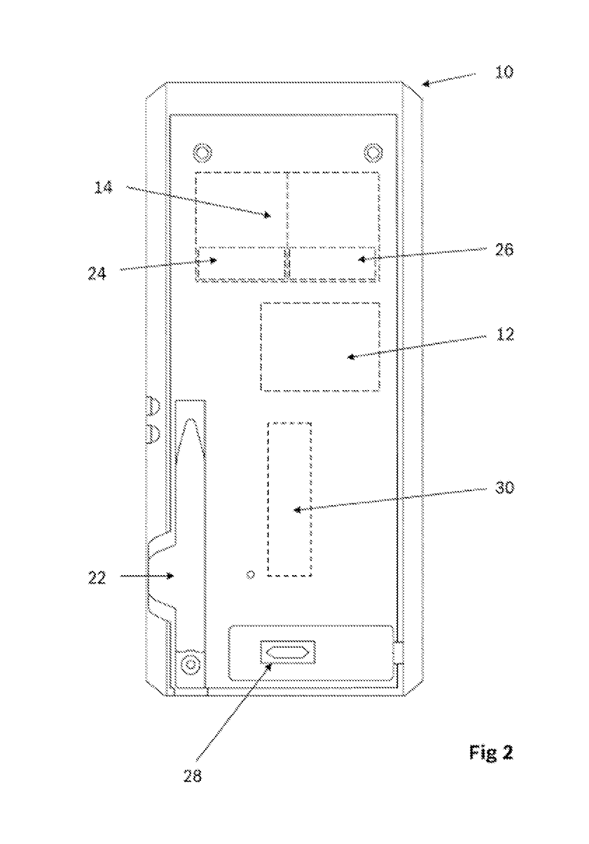

FIG. 1 (front side) and FIG. 2 (rear side) show a measuring apparatus 10 according to the disclosure in the form of a handheld laser distance meter. The measuring apparatus 10 has an evaluation or computation unit 12, an electronic distance measuring means 14, a display 16 and an operating device 18 which are all integrated in the housing 20 of the apparatus 10. Components which are arranged in the housing but are actually not directly visible from the outside are depicted using dashed lines in the figures.

The distance measuring means 14 consists, inter alia, of a transmitting unit for emitting a distance measurement signal and a receiving unit for detecting a returning distance measurement signal. During a distance measurement, the distance measuring means 14 detects a distance between the distance measuring means 14 and a reference point of the distance measurement formed on the apparatus, for example a pivotable measuring stop 22 and a measurement object (not illustrated in any more detail). For this purpose, the means has a laser 24 (not illustrated in any more detail), for example in the form of a laser diode, which emits a laser beam, in particular a modulated laser beam, in the direction of the target or measurement object to be measured. During the distance measurement, the measurement object reflects part of the laser beam back in the direction of the measuring apparatus. A sensor 26 (not illustrated in any more detail) of the receiving unit of the distance measuring means 14 detects part of the reflected light of the laser beam and converts it into an electrical signal for further processing.

The evaluation unit 12 which is electronically connected, inter alia, to the sensor has a calculation routine which allows the distance between the measuring apparatus and a measurement object to be determined using properties of the modulated laser beam. In this case, the evaluation unit 12 evaluates a propagation time or a phase angle and/or an amplitude of the part of the reflected light of the laser beam in order to determine a distance value therefrom. The evaluation unit 12 displays a determined value of the measured distance on the display 16 of the measuring apparatus in a manner visible to the operator.

An operator controls the measuring apparatus 10 using the operating device 18, that is to say can start a measurement, for example, or else can store measured values.

In order to operate the measuring apparatus according to the disclosure, the latter has an energy supply 30 which is permanently installed in the housing 20 of the apparatus 10 and is therefore not directly accessible to the user. In the exemplary embodiment illustrated, the internal energy supply 30 of the measuring apparatus consists of an individual lithium ion cell with a nominal voltage/rated voltage of 3.7 V (1250 mAh).

The energy supply 30 is electrically connected to an interface 28 which can be used to charge the rechargeable battery cell of the measuring apparatus 10 from the outside. In the exemplary embodiment in FIG. 2, the interface is a micro USB interface of the type B. Other types of micro USB interfaces and other USB interfaces are likewise possible, in principle.

The integrated micro USB interface 28 makes it possible to charge the rechargeable battery 30 installed in the apparatus using standardized, that is to say conventional micro USB switched mode power supplies.

In addition, the interface 28 advantageously also allows the measuring apparatus 10 according to the disclosure to communicate with other apparatuses or external applications via a standardized, that is to say conventional micro USB cable.

In this case, communication can be used for interchanging data for the user and/or for interchanging data with other applications, for example also in a production line. It is thus also advantageously possible to subsequently read “concomitantly tracked”, that is to say recorded, data or to install software updates without having to open the apparatus.

This also makes it possible to easily transmit data and/or images from the measuring apparatus according to the disclosure, which are stored on PCs (computers), tablet PCs, PDAs (Personal Digital Assistants) or else so-called smart phones or other storage media, from the measuring apparatus according to the disclosure to the external application or else in the opposite direction.

This also likewise simplifies the loading of measured values directly into an application, for example into a drawing program for creating outlines or sketches or the like.

On the other hand, it is possible to control the apparatus according to the disclosure from the outside via the communication interface and to operate said apparatus in the sense of a remote control, for example.

The interface 28 integrated in the measuring apparatus 10 can also be used to connect further apparatuses, for example a temperature measuring apparatus and/or a moisture measuring apparatus and/or a camera and/or a measuring tape, in particular an electronic measuring tape.

What is claimed is:

1. A distance meter, comprising:
a housing;
a distance measuring mechanism;
an evaluation unit configured to determine distance measured values; and
an energy supply which is permanently installed in the housing,
wherein the energy supply is one or more rechargeable battery cells.

2. The distance meter according to claim 1, wherein the one or more rechargeable battery cells are based on lithium chemistry.

3. The distance meter according to claim 1, wherein the one or more rechargeable battery cells have a nominal voltage in the range of 3 V to 5 V.

4. The distance meter according to claim 1, wherein the one or more rechargeable battery cells is one rechargeable battery cell.

5. The distance meter according to claim 1, further comprising a USB interface, the USB interface being configured to enable charging of the one or more rechargeable battery cells.

6. The distance meter according to claim 5, wherein the USB interface is integrated in the housing of the distance meter.

7. The distance meter according to claim 1, further comprising a communication interface configured to communicate data between the distance meter and an external application.

8. The distance meter according to claim 7, wherein the communication interface is formed by a USB interface.

9. The distance meter according to claim 5, wherein the USB interface has a cover.

10. A system, comprising:
a distance meter including:
a housing;
a distance measuring mechanism;
an evaluation unit configured to determine distance measured values; and
an energy supply which is permanently installed in the housing,
wherein the energy supply is one or more rechargeable battery cells; and
at least one USB cable.

11. The distance meter according to claim 1, wherein the distance meter is a handheld electro-optical distance meter.

12. The distance meter according to claim 3, wherein the one or more rechargeable battery cells have a nominal voltage in the range of 3.5 V to 3.9 V.

13. The distance meter according to claim 5, wherein the USB interface is a micro USB interface.

14. The distance meter according to claim 6, wherein the USB interface is a micro USB interface.

15. The distance meter according to claim 8, wherein the USB interface is micro USB interface.

16. The distance meter according to claim 9, wherein the USB interface is a micro USB interface.
